(19) United States
(12) Patent Application Publication
(10) Pub. No.: US 2025/0372502 A1
(43) Pub. Date: Dec. 4, 2025

(54) CHIP PACKAGE

(71) Applicant: XINTEC INC., Taoyuan City (TW)

(72) Inventors: Wei-Luen SUEN, Taoyuan City (TW); Jiun-Yen LAI, Taoyuan City (TW); Chien Wei CHANG, Taoyuan City (TW); Po-Jung CHEN, Kouhu Township (TW); Tsang-Yu LIU, Zhubei City (TW)

(21) Appl. No.: 19/204,561

(22) Filed: May 11, 2025

Related U.S. Application Data
(60) Provisional application No. 63/654,802, filed on May 31, 2024.

(51) Int. Cl. H01L 23/498

(52) U.S. Cl. CPC H01L 23/49866; H01L 23/49816

(57) ABSTRACT

A chip package includes a semiconductor substrate, an isolation layer, a redistribution layer, a first protection layer, a conductive structure, and a second protection layer. The isolation layer is located on a surface of the semiconductor substrate. The redistribution layer is located on the isolation layer and extends to a conductive pad in a through hole. The first protection layer is located on the redistribution layer and the isolation layer, and a portion of the first protection layer is located in the through hole. The conductive structure is located on the redistribution layer. The second protection layer covers the first protection layer, the isolation layer, and the outer sidewall of the semiconductor substrate. The material of the second protection layer is different from the material of the first protection layer, and the second protection layer surrounds and is in contact with the conductive structure.

### CROSS-REFERENCE TO RELATED APPLICATION

This application claims priority to U.S. Provisional Application Ser. No. 63/654,802, filed May 31, 2024, which is herein incorporated by reference.

### BACKGROUND

### Field of Invention

The present disclosure relates to a chip package.

### Description of Related Art

A chip package includes a semiconductor substrate, an isolation layer, a redistribution layer, a solder ball, and a protection layer (e.g., green paint). Generally speaking, the redistribution layer is a metal composite layer, but the thickness of each metal layer therein is not specially designed. As a result, when the solder ball is disposed on the redistribution layer, it is difficult to reduce a metal stress.

Moreover, although an under bump metallurgy (UBM) layer may be disposed on the redistribution layer before disposing the solder ball on the UBM layer, the material of the redistribution layer and the material of the UBM layer are not specially designed, and thus it is difficult to strengthen structure. The protection layer of the conventional chip package is merely located on one side of the semiconductor substrate on which the solder ball is disposed, and thus it is difficult to protect the outer sidewall of the semiconductor substrate. In addition, an etch process is usually performed on the entire surface of the isolation layer to expose a conductive pad in the through hole of the semiconductor substrate. Therefore, after the isolation layer on the conductive pad is removed, the thickness of the isolation layer on the turning point of the semiconductor substrate adjacent to the through hole is significantly thinner, which may cause an increase in parasitic capacitance.

### SUMMARY

According to some embodiments of the present disclosure, a chip package includes a semiconductor substrate, an isolation layer, a redistribution layer, a first protection layer, a conductive structure, and a second protection layer. The semiconductor substrate has a through hole and a conductive pad in the through hole. The isolation layer is located on a surface of the semiconductor substrate and an inner sidewall of the semiconductor substrate surrounding the through hole. The redistribution layer is located on the isolation layer and extends to the conductive pad. The first protection layer is located on the redistribution layer and the isolation layer, and a portion of the first protection layer is located in the through hole. The conductive structure is located on the redistribution layer. The second protection layer covers the first protection layer, the isolation layer, and the outer sidewall of the semiconductor substrate, in which the material of the second protection layer is different from the material of the first protection layer, and the second protection layer surrounds and is in contact with the conductive structure.

In some embodiments, a material of the redistribution layer is copper only.

In some embodiments, a thickness of the redistribution layer is in a range from 3 μm to 4 μm.

In some embodiments, the chip package further includes a metal composite layer located between the redistribution layer and the conductive structure.

In some embodiments, the metal composite layer includes a copper layer, a nickel layer, and a gold layer, the nickel layer is located between the copper layer and the gold layer, and the copper layer is located between the redistribution layer and the nickel layer.

In some embodiments, a portion of the first protection layer is located between the metal composite layer and the redistribution layer.

In some embodiments, a material of the conductive structure is nickel-free.

In some embodiments, the conductive structure is in direct contact with the redistribution layer.

In some embodiments, a thickness of the redistribution layer is in a range from 6.5 μm to 7.5 μm.

In some embodiments, a material of the conductive structure includes nickel having a weight percentage in the conductive structure in a range from 0.045% to 0.055%.

In some embodiments, a material of the first protection layer is polyimide, and a material of the second protection layer is epoxy.

In some embodiments, a thickness of the isolation layer on an intersection of the surface and the inner sidewall of the semiconductor substrate is the same as a thickness of the isolation layer on the surface of the semiconductor substrate.

In some embodiments, the isolation layer on the conductive pad has an underfoot structure tapering away from the inner sidewall.

In the aforementioned embodiments of the present disclosure, since the chip package has the first protection layer and the second protection layer, the second protection layer does not enter the through hole to facilitate reducing stress. Moreover, the second protection layer can surround the conductive structure and cover the outer sidewall of the semiconductor substrate, so that the stability of the conductive structure can be improved and the outer sidewall of the semiconductor substrate can be protected.

According to some embodiments of the present disclosure, a chip package includes a semiconductor substrate, an isolation layer, a redistribution layer, a conductive structure, and a protection layer. The semiconductor substrate has a through hole and a conductive pad in the through hole. The isolation layer is located on a surface of the semiconductor substrate and the inner sidewall of the semiconductor substrate surrounding the through hole. The redistribution layer is located on the isolation layer and extends to the conductive pad. The redistribution layer includes a copper layer, a nickel layer, and a gold layer, the nickel layer is located between the copper layer and the gold layer, the copper layer is located between the isolation layer and the nickel layer, and a thickness of the copper layer is greater than a sum of a thickness of the nickel layer and a thickness of the gold layer. The conductive structure is located on the redistribution layer. The protection layer covers the redistribution layer, the isolation layer, and an outer sidewall of the semiconductor substrate. The protection layer surrounds and is in contact with the conductive structure.

In some embodiments, the thickness of the copper layer is in a range from 6.5 μm to 7.5 μm, a thickness of the nickel layer is in a range from 0.05 μm to 0.5 μm, and a thickness of the gold layer is in a range from 0.025 μm to 0.035 μm.

In some embodiments, a material of the conductive structure is nickel-free.

In some embodiments, the conductive structure is in direct contact with the redistribution layer.

In some embodiments, a portion of the protection layer is located in the through hole.

In some embodiments, a thickness of the isolation layer on an intersection of the surface and the inner sidewall of the semiconductor substrate is the same as a thickness of the isolation layer on the surface of the semiconductor substrate.

In some embodiments, the isolation layer on the conductive pad has an underfoot structure tapering away from the inner sidewall.

In the aforementioned embodiments of the present disclosure, since the redistribution layer includes the copper layer, the nickel layer, and the gold layer, and the nickel layer is located between the copper layer and the gold layer, and the copper layer is located between the isolation layer and the nickel layer, and the thickness of the copper layer is greater than the sum of the thickness of the nickel layer and the thickness of the gold layer, metal stress can be effectively reduced. Furthermore, because the protection layer may surround the conductive structure and cover the outer sidewall of the semiconductor substrate, the stability of the conductive structure can be improved and the outer sidewall of the semiconductor substrate can be protected.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIG. 2 is a partially enlarged view of a metal composite layer of FIG. 1.

FIG. 3 is a partially enlarged view of a semiconductor substrate, an isolation layer, and a redistribution layer in an area A of FIG. 1.

FIG. 4 is a partially enlarged view of the semiconductor substrate, the isolation layer, the redistribution layer, and a conductive pad in an area B of FIG. 1.

FIG. 5 is a cross-sectional view of a chip package according to another embodiment of the present disclosure.

FIG. 6 is a cross-sectional view of a chip package according to still another embodiment of the present disclosure.

FIG. 7 is a partially enlarged view of the redistribution layer of FIG. 6.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

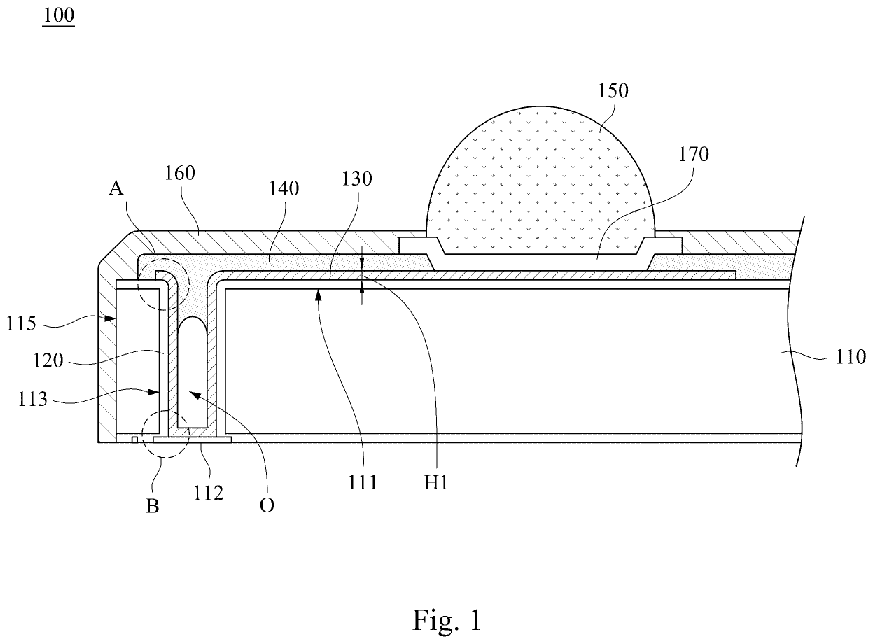

FIG. 1 is a cross-sectional view of a chip package 100 according to one embodiment of the present disclosure. As shown in FIG. 1, the chip package 100 includes a semiconductor substrate 110, an isolation layer 120, a redistribution layer 130, a first protection layer 140, a conductive structure 150, and a second protection layer 160. The semiconductor substrate 110 has a through hole O and a conductive pad 112 in the through hole O. In other words, the position of the conductive pad 112 corresponds to the position of the through hole O, and the conductive pad 112 and the through hole O are overlap in a vertical direction. The semiconductor substrate 110 has an inner sidewall 113 surrounding the through hole O. The isolation layer 120 is located on a surface 111 and the inner sidewall 113 of the semiconductor substrate 110. In some embodiments, the material of the semiconductor substrate 110 may include silicon, such as a silicon substrate. The material of the isolation layer 120 may be silicon dioxide. The redistribution layer 130 is located on the isolation layer 120 and extends to the conductive pad 112. The first protection layer 140 is located on the redistribution layer 130 and the isolation layer 120, and a portion of the first protection layer 140 is located in the through hole O. The conductive structure 150 is located on the redistribution layer 130. The second protection layer 160 covers the first protection layer 140, the isolation layer 120, and an outer sidewall 115 of the semiconductor substrate 110. The material of the second protection layer 160 is different from the material of the first protection layer 140, and the second protection layer 160 surrounds and is in contact with the conductive structure 150. For example, the material of the first protection layer 140 may be polyimide (PI), and the material of the second protection layer 160 may be epoxy (e.g., solder mask green paint).

Specifically, since the chip package 100 has the first protection layer 140 and the second protection layer 160, the second protection layer 160 does not enter the through hole O to facilitate reducing stress. Moreover, the second protection layer 160 can surround the conductive structure 150 and cover the outer sidewall 115 of the semiconductor substrate 110, so that the stability of the conductive structure 150 can be improved and the outer sidewall 115 of the semiconductor substrate 110 can be protected.

In this embodiment, the material of the redistribution layer 130 is copper only. That is, the redistribution layer 130 is pure copper layer. The thickness H1 of the redistribution layer 130 is in a range from 3 μm to 4 μm, such as 3.5 μm. The material of the conductive structure 150 includes tin, but is nickel-free. In such a configuration, metal stress can be effectively reduced.

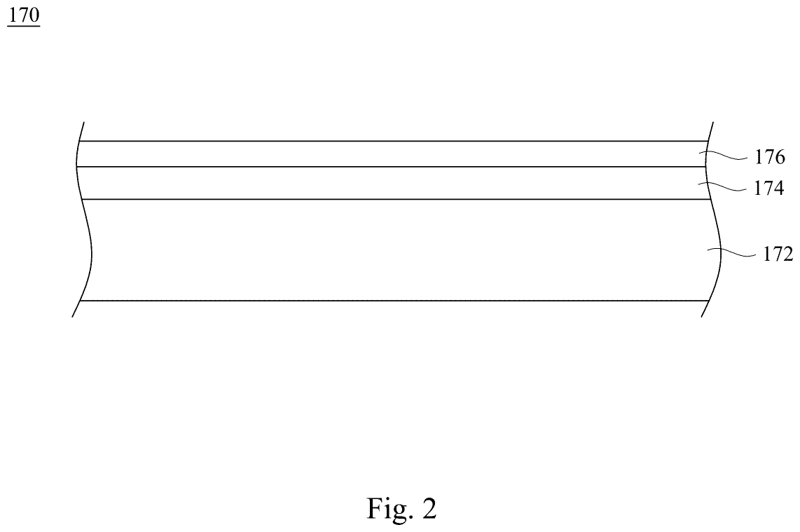

FIG. 2 is a partially enlarged view of a metal composite layer 170 of FIG. 1. As shown in FIG. 1 and FIG. 2, the chip package 100 may further include the metal composite layer 170 located between the redistribution layer 130 and the conductive structure 150. A portion of the first protection layer 140 is located between the metal composite layer 170 and the redistribution layer 130, and the second protection layer 160 surrounds and is in contact with the metal composite layer 170. The metal composite layer 170 includes a copper layer 172, a nickel layer 174, and a gold layer 176. The nickel layer 174 is located between the copper layer 172 and the gold layer 176, and the copper layer 172 is located between the redistribution layer 130 and the nickel layer 174. In such a configuration, the stability of the conductive structure 150 can be improved.

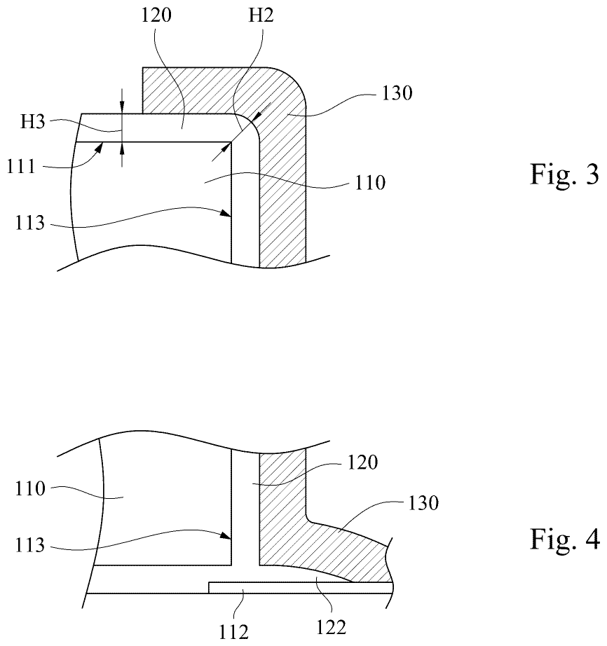

FIG. 3 is a partially enlarged view of the semiconductor substrate 110, the isolation layer 120, and the redistribution layer 130 in an area A of FIG. 1. As shown in FIG. 1 and FIG. 3, the isolation layer 120 is formed by a deposition process and etching after the coverage of photoresist. Comparing the isolation layer 120 and an isolation layer that is formed by directly oxidizing a silicon substrate, a thickness H2 of the isolation layer 120 of the present disclosure on the intersection of the surface 111 and the inner sidewall 113 of the semiconductor substrate 110 is the same as a thickness H3 of the isolation layer 120 on the surface 111 of the semiconductor substrate 110, and may be also the same as the thickness of the isolation layer 120 on the inner sidewall 113 of the semiconductor substrate 110. In other words, the isolation layer 120 has a uniform thickness that will not become significantly thinner on the intersection of the surface 111 and the inner sidewall 113, and thus there is no obvious chamfer inclined surface. In such a configuration, parasitic capacitance can be effectively reduced.

FIG. 4 is a partially enlarged view of the semiconductor substrate 110, the isolation layer 120, the redistribution layer 130, and the conductive pad 112 in an area B of FIG. 1. As shown in FIG. 1 and FIG. 4, the isolation layer 120 on the conductive pad 112 has an underfoot structure 122 that tapers away from the inner sidewall 113. The position of the end of the underfoot structure 122 may be defined by the vertical position covered by photoresist when etching the isolation layer 120.

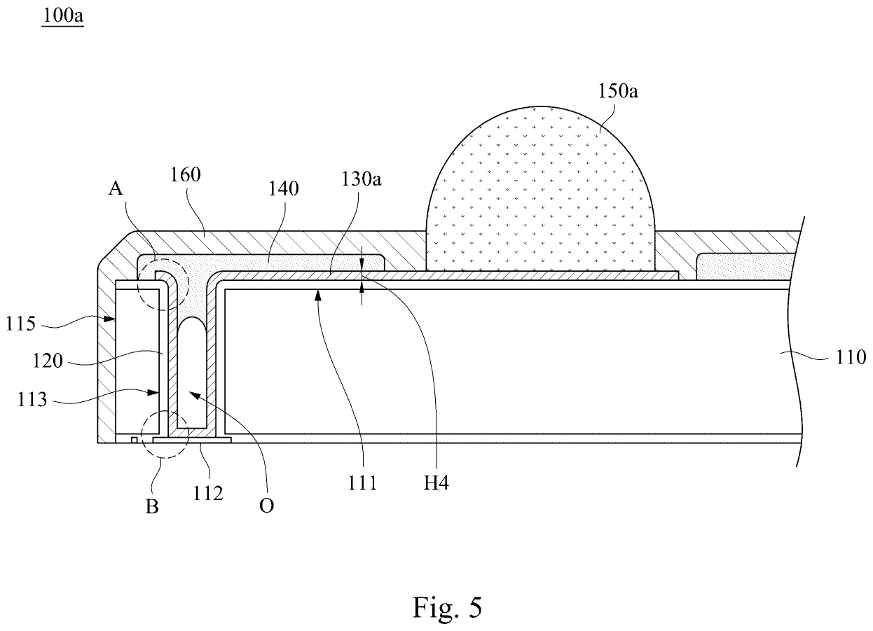

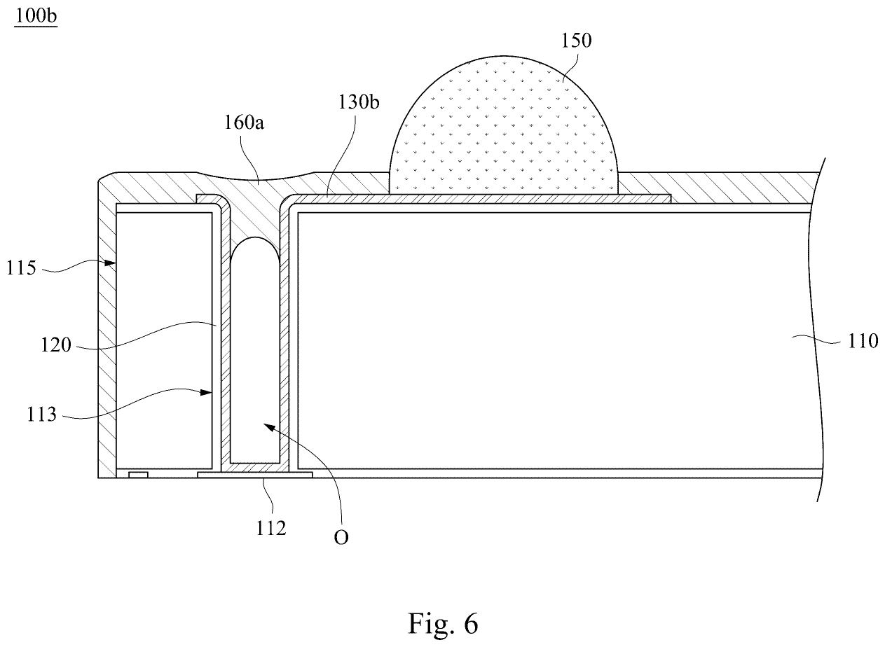

It is to be noted that the connection relationships, the materials, and the advantages of the elements described above will not be repeated in the following description. In the following description, other types of chip packages will be explained. Moreover, the design of the isolation layer 120 in FIGS. 3 and 4 may be applied to a chip package 100a of FIG. 5 and a chip package 100b of FIG. 6.

FIG. 5 is a cross-sectional view of the chip package 100a according to another embodiment of the present disclosure. The chip package 100a includes the semiconductor substrate 110, the isolation layer 120, a redistribution layer 130a, the first protection layer 140, a conductive structure 150a, and the second protection layer 160. The difference between this embodiment and the embodiment of FIG. 1 is that the chip package 100a has no metal composite layer 170 of FIG. 1, and the material of the conductive structure 150a includes nickel and tin. The conductive structure 150a of the chip package 100a is in direct contact with the redistribution layer 130a. In addition, nickel of the conductive structure 150a has a weight percentage in the conductive structure 150a in a range from 0.045% to 0.055%, such as 0.05%. A thickness H4 of the redistribution layer 130a is greater than the thickness H1 of the redistribution layer 130 of FIG. 1. The thickness H4 of the redistribution layer 130a is in a range from 6.5 μm to 7.5 μm, such as 7 μm. In this embodiment, the second protection layer 160 of the chip package 100a has a portion between the first protection layer 140 and the conductive structure 150a.

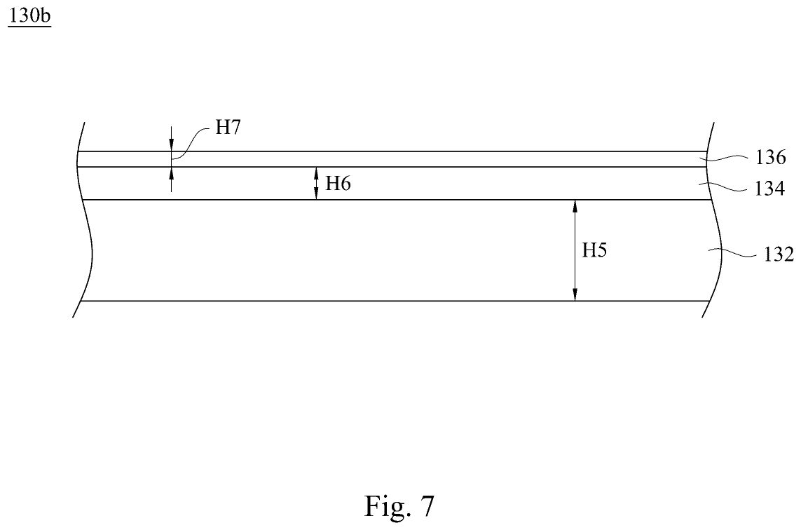

FIG. 6 is a cross-sectional view of the chip package 100b according to still another embodiment of the present disclosure. FIG. 7 is a partially enlarged view of a redistribution layer 130b of FIG. 6. As shown in FIG. 6 and FIG. 7, the chip package 100b includes the semiconductor substrate 110, the isolation layer 120, a redistribution layer 130b, the conductive structure 150, and a protection layer 160a. The difference between this embodiment and the embodiment of FIG. 5 is that the redistribution layer 130b of the chip package 100b includes a copper layer 132, a nickel layer 134, and a gold layer 136. The chip package 100b merely has the single protection layer 160a, and the material of the conductive structure 150 includes tin but no nickel. The nickel layer 134 is located between the copper layer 132 and the gold layer 136, and the copper layer 132 is located between the isolation layer 120 and the nickel layer 134. A thickness H5 of the copper layer 132 is greater than a thickness H6 of the nickel layer 134 and a thickness H7 of the gold layer 136, and is greater than the sum of the thickness H6 of the nickel layer 134 and the thickness H7 of the gold layer 136. In this embodiment, the thickness H5 of the copper layer 132 is in a range from 6.5 μm to 7.5 μm (e.g., 7 μm), the thickness H6 of the nickel layer 134 is in a range from 0.05 μm to 0.5 μm (e.g., 0.25 μm), and the thickness H7 of the gold layer 136 is in a range from 0.025 μm to 0.035 μm (e.g., 0.03 μm). The protection layer 160a covers the redistribution layer 130b, the isolation layer 120, and the outer sidewall 115 of the semiconductor substrate 110, and the protection layer 160a surrounds and is in contact with the conductive structure 150. Moreover, a portion of the protection layer 160a is located in the through hole O of the semiconductor substrate 110.

Since the redistribution layer 130b includes the copper layer 132, the nickel layer 134, and the gold layer 136, and the nickel layer 134 is located between the copper layer 132 and the gold layer 136, and the copper layer 132 is located between the isolation layer 120 and the nickel layer 134, and the thickness H5 of the copper layer 132 is greater than the sum of the thicknesses of the nickel layer 134 and the gold layer 136, metal stress can be effectively reduced. Furthermore, because the protection layer 160a may surround the conductive structure 150 and cover the outer sidewall 115 of the semiconductor substrate 110, the stability of the conductive structure 150 can be improved and the outer sidewall 115 of the semiconductor substrate 110 can be protected.

In some embodiments, the nickel layer 134 may be formed by electroplating, and the gold layer 136 may be formed by electroless plating, but the present disclosure is not limited in this regard.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a semiconductor substrate having a through hole and a conductive pad in the through hole;
an isolation layer located on a surface of the semiconductor substrate and an inner sidewall of the semiconductor substrate surrounding the through hole;
a redistribution layer located on the isolation layer and extending to the conductive pad;
a first protection layer located on the redistribution layer and the isolation layer, wherein a portion of the first protection layer is located in the through hole;
a conductive structure located on the redistribution layer; and
a second protection layer covering the first protection layer, the isolation layer, and an outer sidewall of the semiconductor substrate, wherein a material of the second protection layer is different from a material of the first protection layer, and the second protection layer surrounds and is in contact with the conductive structure.

2. The chip package of claim 1, wherein a material of the redistribution layer is copper only.

3. The chip package of claim 1, wherein a thickness of the redistribution layer is in a range from 3 μm to 4 μm.

4. The chip package of claim 1, further comprising:
a metal composite layer located between the redistribution layer and the conductive structure.

5. The chip package of claim 4, wherein the metal composite layer comprises a copper layer, a nickel layer, and a gold layer, the nickel layer is located between the copper layer and the gold layer, and the copper layer is located between the redistribution layer and the nickel layer.

6. The chip package of claim 4, wherein a portion of the first protection layer is located between the metal composite layer and the redistribution layer.

7. The chip package of claim 1, wherein a material of the conductive structure is nickel-free.

8. The chip package of claim 1, wherein the conductive structure is in direct contact with the redistribution layer.

9. The chip package of claim 1, wherein a thickness of the redistribution layer is in a range from 6.5 μm to 7.5 μm.

10. The chip package of claim 1, wherein a material of the conductive structure comprises nickel having a weight percentage in the conductive structure in a range from 0.045% to 0.055%.

11. The chip package of claim 1, wherein a material of the first protection layer is polyimide, and a material of the second protection layer is epoxy.

12. The chip package of claim 1, wherein a thickness of the isolation layer on an intersection of the surface and the inner sidewall of the semiconductor substrate is the same as a thickness of the isolation layer on the surface of the semiconductor substrate.

13. The chip package of claim 1, wherein the isolation layer on the conductive pad has an underfoot structure tapering away from the inner sidewall.

14. A chip package, comprising:
a semiconductor substrate having a through hole and a conductive pad in the through hole;
an isolation layer located on a surface of the semiconductor substrate and an inner sidewall of the semiconductor substrate surrounding the through hole;
a redistribution layer located on the isolation layer and extending to the conductive pad, wherein the redistribution layer comprises a copper layer, a nickel layer, and a gold layer, the nickel layer is located between the copper layer and the gold layer, the copper layer is located between the isolation layer and the nickel layer, and a thickness of the copper layer is greater than a sum of a thickness of the nickel layer and a thickness of the gold layer;
a conductive structure located on the redistribution layer; and
a protection layer covering the redistribution layer, the isolation layer, and an outer sidewall of the semiconductor substrate, wherein the protection layer surrounds and is in contact with the conductive structure.

15. The chip package of claim 14, wherein the thickness of the copper layer is in a range from 6.5 μm to 7.5 μm, a thickness of the nickel layer is in a range from 0.05 μm to 0.5 μm, and a thickness of the gold layer is in a range from 0.025 μm to 0.035 μm.

16. The chip package of claim 14, wherein a material of the conductive structure is nickel-free.

17. The chip package of claim 14, wherein the conductive structure is in direct contact with the redistribution layer.

18. The chip package of claim 14, wherein a portion of the protection layer is located in the through hole.

19. The chip package of claim 14, wherein a thickness of the isolation layer on an intersection of the surface and the inner sidewall of the semiconductor substrate is the same as a thickness of the isolation layer on the surface of the semiconductor substrate.

20. The chip package of claim 14, wherein the isolation layer on the conductive pad has an underfoot structure tapering away from the inner sidewall.
